(19) United States
(12) Patent Application Publication
(10) Pub. No.: US 2010/0096658 A1
(43) Pub. Date: Apr. 22, 2010

(54) Structure of Light Emitting Diode

(76) Inventors: Ming-Chang Wu, Tucheng City (TW); Chih-Yang Hsu, Tucheng City (TW); Ming-Yu Hsu, Tucheng City (TW); Chih-Hung Wei, Tucheng City (TW)

Correspondence Address: Stuart D. Frenkel;Frenkel & Associates, P.C., Suite 330, 3975 University Drive, Fairfax, VA, 22030, US

(21) Appl. No.: 12/254,049

(22) Filed: Oct. 20, 2008

(51) Int. Cl. H01L 33/00

(52) U.S. Cl. 257/99; 257/E33.001

(57) ABSTRACT

An improved structure of light emitting diode comprises that a copper clad laminate is made with a rectangular type slot thereon and a ring type slot on the outside boundary to enclose the rectangular type slot, while side wall of the slot form a natural guide angle with the surface of the copper clad laminate to further form an island type platform; a conductor being made between rectangular type slot and ring type slot is penetrated through the copper clad laminate and externally enclosed by the insulator thereby allowing conductor to be insulated; a light emitting diode chip is installed thereon; a fluorescent glue is optionally installed on the light emitting diode with a covering range smaller than the natural guiding angle of the rectangular type slot, wherein the copper clad laminate is installed on the printed circuit board.

### FIELD OF THE INVENTION

The invention is related to a light emitting diode, more particularly to an improved structure of light emitting diode.

### BACKGROUND OF THE INVENTION

The conventional method for white light emitting diode packaging is by utilizing a lens to enclose the diode chip for protection, wherein the lens is usually fixed by injection-forming method or by externally applied molding method.

However, the lens is easily stripped off when pushed by an external force to protect the chip effectively. Further, waste heat is generated for long term use of the light emitting diode chip to cause the hot expansion and cold shrinking effect on the outer shell thereby making the lens to fall off after some time of use. All of these scenarios may reduce the brightness of light source, therefore it is not suitable for use in mass production. Another embodiment for light emitting diode manufacture mostly adopts blue or violet series light emitting diode chips, wherein a light emitting diode chip being made on the substrate is electrified to emit light and is covered by a sealing glue (silicon glue or epoxy resin) on top of the light emitting diode chip thereby completing the packaging structure of the light emitting diode; nonetheless, extreme precision is required during the dispensing process, while it is easy to flow out onto the side substrate in packaging manufacturing process thereby affecting the packaging and work life of the whole set of light emitting diode chips, and that is a big disadvantage for the light emitting diodes.

In view of the imperfections of conventional arts, the invention discloses an improved structure of light emitting diode aiming to solve the imperfections of conventional arts.

### SUMMARY OF THE INVENTION

The main purpose of the invention is to disclose an improved structure of light emitting diode, wherein a rectangular type slot and ring type slot are made on the copper clad laminate to further form an island type platform, and side wall of the slot form a natural guide angle θ with the surface of the copper clad laminate; wherein when dispensing the transparent glue or fluorescent glue, the transparent glue and fluorescent glue do not diffuse outside the slot due to surface tension thereby achieving a perfect adhering-packaging effect.

Another purpose of the invention is to disclose an improved structure of light emitting diode, wherein the natural guiding angle is made by etching, reverse electroplating or machining methods to be close to a perpendicular angle so as to make the dispensing-packaging process more perfect.

To achieve the above purpose, the invention is related to a light emitting diode, more particularly to an improved structure of light emitting diodes, wherein it comprises that a copper clad laminate is made with a rectangular type slot thereon and a ring type slot is made on the outside boundary to enclose the rectangular type slot, wherein side wall of the slot form a natural guide angle with the surface of the copper clad laminate and it is further formed with an island type platform; a conductor being made between rectangular type slot and ring type slot is penetrated through the copper clad laminate and is externally enclosed by the insulator thereby allowing conductor to be insulated from the copper clad laminate; a light emitting diode chip is installed on the copper clad laminate; a fluorescent glue can be optionally installed on the light emitting diode while allowing the covering range of the fluorescent glue to be smaller than the natural guiding angle of the rectangular type slot; a transparent glue being covered on the copper clad laminate enclosed the fluorescent glue and the surface of the copper clad laminate, wherein the covering range of the transparent glue shall be smaller than natural guiding angle of the ring type slot; and a printed circuit board, wherein above said copper clad laminate is installed on the printed circuit board, so that the dispensed transparent glue and fluorescent glue are difficult to diffuse due to stoppage by the natural guiding angle thereby providing convenience for packaging the light emitting diode.

The purpose, technical contents, characteristics and achieved effectiveness of the invention are described in detail by the specific embodiments and the accompanied figures in the following.

### BRIEF DESCRIPTION OF THE DRAWINGS

FIG. 1 is a schematic view showing an improved structure of the light emitting diode of the invention.

FIG. 2 is a partial enlarged view showing the circular type slots of the improved structure of the light emitting diode of the invention.

FIG. 3 is a partial enlarged view showing the rectangular type slots of the improved structure of the light emitting diode of the invention.

FIG. 4 shows the embodiment of the improved structure of light emitting diode of the invention.

FIG. 5 shows another embodiment of the improved structure of light emitting diode of the invention.

FIG. 6 is a top view of the embodiment of the invention showing a plurality of improved structures of light emitting diodes.

FIG. 7 is a bottom view of the embodiment of the invention showing a plurality of improved structures of light emitting diodes.

### DETAILED DESCRIPTION OF THE PREFERRED EMBODIMENTS

For the convenience of examiners to succinctly understand the other features and advantages of the invention as well as to further reveal its achieved effectiveness, the invention is described in detail with the accompanied figures in the following:

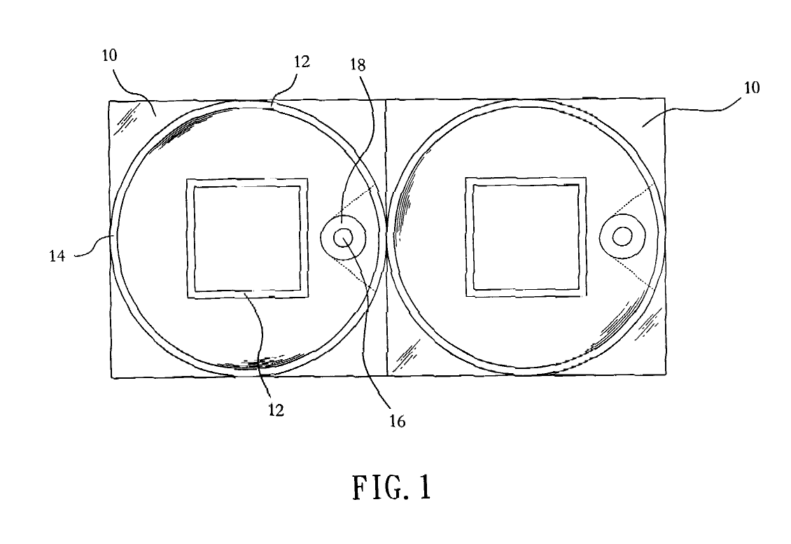

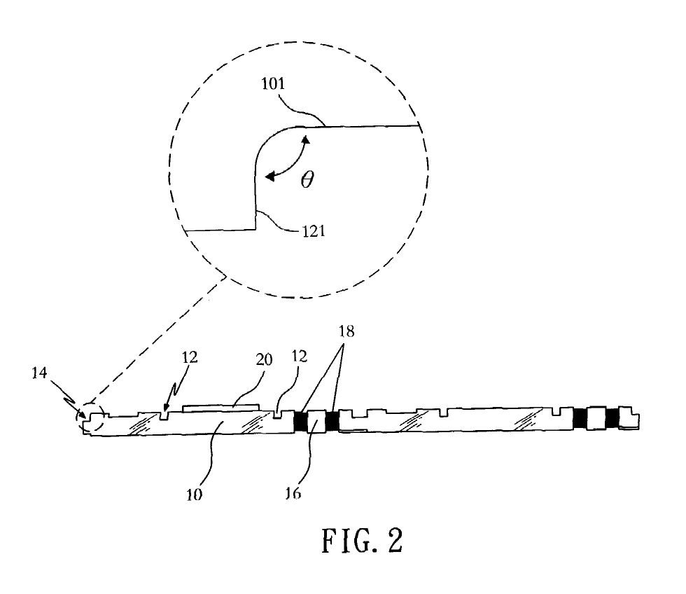

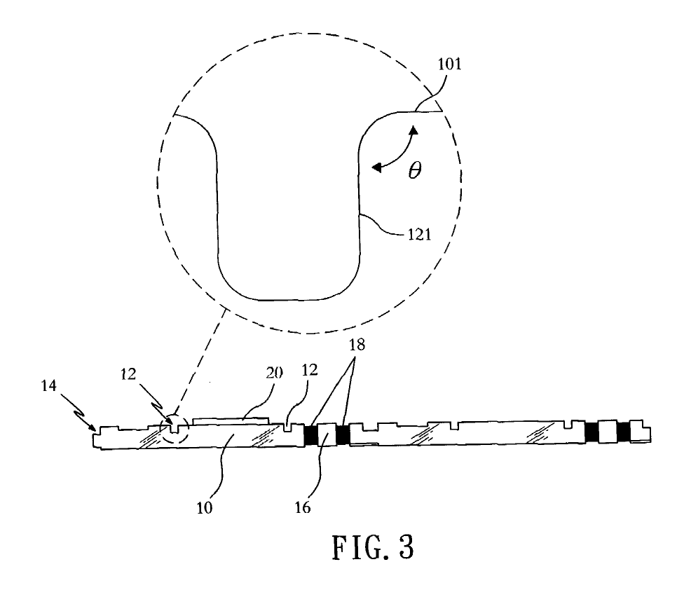

FIG. 1 is a schematic view showing an improved structure of the light emitting diode of the invention. FIG. 2 is a partial enlarged view showing the circular type slots of the improved structure of the light emitting diode of the invention. FIG. 3 is a partial enlarged view showing the rectangular type slots of the improved structure of the light emitting diode of the invention. As shown in the figure, a copper clad laminate 10 or a conductive substrate is made with a rectangular type slot 12 thereon to further form a island type platform, and a ring type slot 14 is made on the outside boundary of slot 12 to further form another island type platform to enclose the rectangular type slot 12, wherein side wall 121 of the slot form a natural guide angle θ with the surface 101 of the copper clad laminate; a conductor 16 being made between rectangular type slot 12 and ring type slot 14 is penetrated through the copper clad laminate 10 and is externally enclosed by the insulator 18 thereby allowing conductor 16 to be insulated from the copper clad laminate 10; then a light emitting diode chip 20 is installed on the copper clad laminator 10 for earthing or electrical conduction between the copper clad laminate 10 and conductor 16. The thickness of copper clad laminate 10 is around 0.1 mm to 0.5 mm; the depths of rectangular type slot 12 and ring type slot 14 being made by etching, reverse electroplating or machining methods are between 0.03 mm to 0.1 mm.

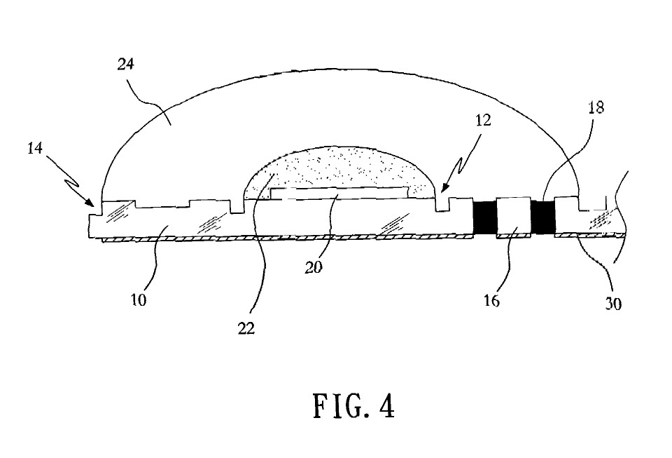

FIG. 4 shows the embodiment of the improved structure of light emitting diode of the invention; as shown in the figure, the light emitting diode chip 20 can be optionally covered with a fluorescent glue 22, wherein covering range of the fluorescent glue 22 shall be smaller than the natural guiding angle θ of the rectangular type slot 12, wherein the natural guiding angle θ is close to 90°, so that fluorescent glue 22 does not easily diffuse into the rectangular type slot 12, and after the fluorescent glue 22 is dried, a little of transparent glue 24 can be dispensed on the copper clad laminate 10 to simultaneously cover the fluorescent glue 22 and copper clad laminate 10, wherein covering range of the transparent glue 24 shall be smaller than the natural guiding angle θ of the ring type slot 14; wherein if the fluorescent glue 22 is not employed, the transparent glue 24 can be applied directly also, besides, the island type platform further includes a sandblasted roughened surface to enhance the adhesive force of transparent glue. The above said copper clad laminate 10 is installed on a printed circuit board 30, wherein the rectangular type slot 12, ring type slot 14 and their natural guiding angle θ are made by etching, reverse electroplating or machining methods; a text or mark being further included between the rectangular type slot 12 and ring type slot 14 is also made by etching, reverse electroplating or machining methods to achieve the purpose of advertising and showing up the products.

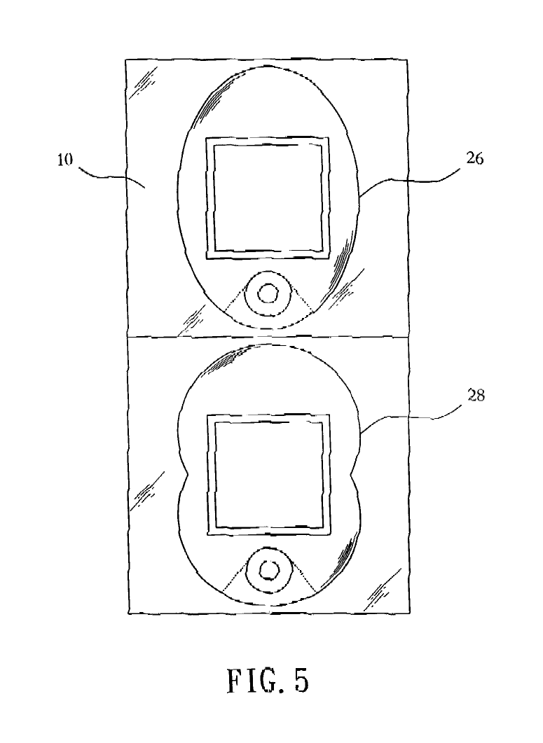

FIG. 5 shows another embodiment of the improved structure of light emitting diode of the invention; as shown in the figure, the ring type slot 14 and rectangular type slot 12 on the copper clad laminate 10 not only can be made by etching, reverse electroplating or machining methods to the circular shape, but also can be made by etching, reverse electroplating or machining methods to various irregular ring shapes such as elliptical shape 26 or double ring shape 28 and further made with the natural guiding angle 0 to achieve the same effectiveness of avoiding diffusion during glue dispensing and packaging process without letting transparent glue 24 or fluorescent glue 22 to diffuse to outside of the slot.

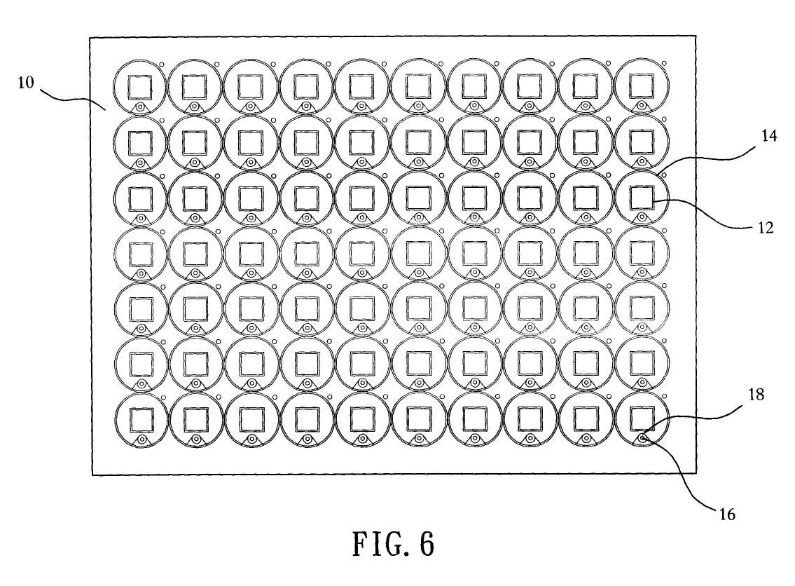

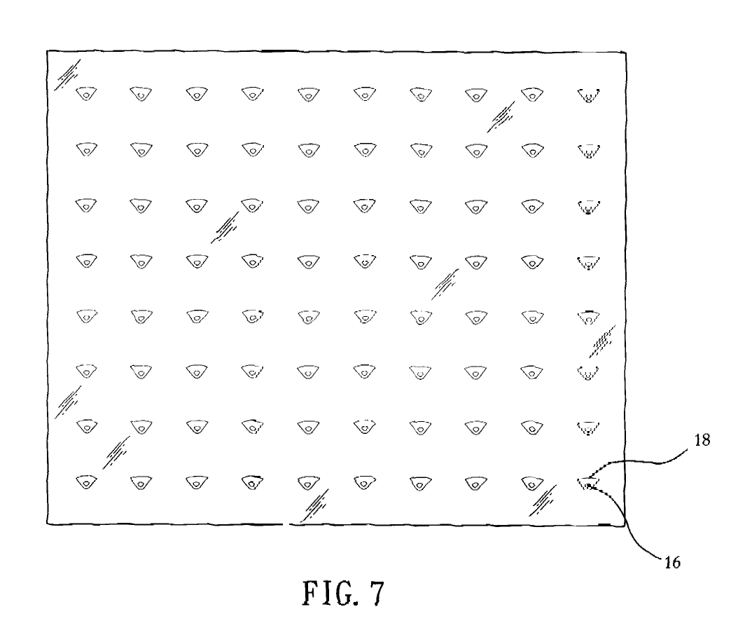

FIG. 6 is a top view of the embodiment of the invention showing a plurality of improved structures of light emitting diodes. FIG. 7 is a bottom view of the embodiment of the invention showing a plurality of improved structures of light emitting diodes. As shown in the figures, the insulator 18 and conductor 16 being made on the copper clad laminate 10 are penetratingly connected through out the copper clad laminate 10, then a plurality of light emitting diode chips 20 are installed on the copper clad laminate 10, wherein the rectangular type slot 12 and ring type slot 14 being installed on the copper clad laminate 10 can be repetitively arranged in linear or rectangular patterns through the utilization dispensing the transparent glue 24 and fluorescent glue 22 on the above said light emitting diode chips 20 for packaging thereby causing the transparent glue 24 and fluorescent glue 22 uneasy to diffuse due to surface tension produced by the natural guiding angle θ and is then convenient for packaging to attain the lighting surface formed by multi-light sources.

As summarized from above descriptions, the invention has been achieving the intended improved effectiveness by breaking through the structure limitation of prior arts and has been beyond the thought of those who are skilled in the arts; further, the progressiveness and practical usefulness of the invention are unpublicized before the patent application that are clearly conforming to the conditions of patent application, therefore it is applied for patent according to the law herein, and your esteemed bureau's approval on the application to encourage future more inventions will be greatly appreciated.

The above said embodiments merely described the technical thought and characteristics of the invention that is mainly purposed to allow those skilled in the arts to familiarize with the content of the invention and to execute accordingly, and is not limiting the patent scope of the invention; hence, all equivalent changes or modifications based on the disclosed spirits of the invention shall still be covered in the claims of the invention.

What is claimed is:

1. An improved structure of light emitting diode comprises at least the following:
A copper clad laminate is made with a rectangular type slot thereon and a ring type slot is made on the outside boundary to enclose the rectangular type slot, wherein side wall of the slot form a natural guide angle θ with the surface of the copper clad laminate and it is further formed with an island type platform;
A conductor being made between rectangular type slot and ring type slot is penetrated through the copper clad laminate and is externally enclosed by the insulator thereby allowing conductor to be insulated from the copper clad laminate;
A light emitting diode chip is installed on the copper clad laminate;
A transparent glue being covered on the copper clad laminate enclosed the fluorescent glue and the surface of the copper clad laminate, wherein the covering range of the transparent glue shall be smaller than natural guiding angle of the ring type slot; and
A printed circuit board, wherein above said copper clad laminate is installed on the printed circuit board.

2. The improved structure of light emitting diode as claimed in claim 1, wherein the rectangular type slot is made by etching, reverse electroplating or machining methods.

3. The improved structure of light emitting diode as claimed in claim 1, wherein the ring type slot is made by etching, reverse electroplating or machining methods.

4. The improved structure of light emitting diode as claimed in claim 1, wherein the natural guiding angle is made by etching, reverse electroplating or machining methods.

5. The improved structure of light emitting diode as claimed in claim 1, wherein a text or a mark is further included between the rectangular type slot and ring type slot.

6. The improved structure of light emitting diode as claimed in claim 5, wherein the text or mark is made by etching, reverse electroplating or machining methods.

7. The improved structure of light emitting diode as claimed in claim 1, wherein the natural guiding angle is made close to 90°.

8. The improved structure of light emitting diode as claimed in claim 1, wherein the thickness of the copper clad laminate is 0.1 mm to 0.5 mm.

9. The improved structure of light emitting diode as claimed in claim 1, wherein the depths of the rectangular type slot and ring type slot are 0.03 mm to 0.1 mm.

10. The improved structure of light emitting diode as claimed in claim 1, wherein the rectangular type slots and ring type slots being installed on the copper clad laminate are repetitively arranged in linear patterns.

11. The improved structure of light emitting diode as claimed in claim 1, wherein the rectangular type slots and ring type slots being installed on the copper clad laminate are repetitively arranged in rectangular patterns.

12. The improved structure of light emitting diode as claimed in claim 1, wherein the rectangular type slots and ring type slots being installed on the copper clad laminate are repetitively arranged.

13. The improved structure of light emitting diode as claimed in claim 1, wherein the light emitting diode chip is further covered by a fluorescent glue, wherein the covering range of the fluorescent glue shall be smaller than the natural guiding angle of the rectangular type slot.

14. The improved structure of light emitting diode as claimed in claim 1, wherein the island type platform further includes a sandblasted roughened surface to enhance the adhesive force of transparent glue.

15. The improved structure of light emitting diode as claimed in claim 1, wherein the copper clad laminate can be an electricity conductive substrate.

16. The improved structure of light emitting diode as claimed in claim 1, wherein the appearance of the rectangular type slot and the ring type slot can be in any shapes.
